(19) United States
(12) Patent Application Publication
(10) Pub. No.: US 2026/0009826 A1
(43) Pub. Date: Jan. 8, 2026

(54) METHOD FOR DETERMINING THE ELECTRIC POTENTIALS OF THE PHASES OF A POLYPHASE MOTOR

(71) Applicant: ARIANEGROUP SAS, Les Mureaux (FR)

(72) Inventor: François MALRAIT, Vernon Cedex (FR)

(73) Assignee: ARIANEGROUP SAS, Les Mureaux (FR)

(21) Appl. No.: 19/119,323

(22) PCT Filed: Oct. 13, 2023
(86) PCT No.: PCT/FR2023/051601

§ 371 Date: Apr. 8, 2025

(30) Foreign Application Priority Data
Oct. 14, 2022 (FR) FR2210631

(51) Int. Cl. G01R 19/165; G01R 31/34

(52) U.S. Cl. CPC G01R 19/16566; G01R 31/343

(57) ABSTRACT

A method (100) for determining potentials (Vᵢ) across the terminals of the N phases of a motor, N being an integer greater than or equal to 4, comprising:
determining (102) reference potentials (V_{REF_i}) across the terminals of the N phases for a defined drive voltage V_{MAG} (101) of phase θ, with i between 1 and N and

$${V}_{REF \_ i} = {V}_{MAG} cos ( θ - \frac{2 π}{N} ( i - 1 ) )$$

comparing (103) the reference potentials to a first threshold (seuil 1);
if the reference potentials are all less than or equal to the first threshold (104), then the potentials across the terminals of the N phases are equal to the reference potentials, or if at least one of the reference potentials is greater than the first threshold, comparing (105) these potentials to a second threshold (seuil 2) greater than the first threshold;
if these reference potentials are all less than or equal to the second threshold (106), then the potentials across the terminals of the N phases are Vᵢ=V_{REF_i}+V_{H}, with

$${V}_{H} = \frac{{max}_{k = 1 … N} ( {V}_{{REF}_{k}} ) + {min}_{k = 1 … N} ( {V}_{{REF}_{k}} )}{2}$$

or if at least one of the potentials is greater than the second threshold (107), then the potentials across the terminals of the N phases are Vᵢ=V_{REF_i}+V_{S_i}+V_{HN}, with V_{HN} and V_{S_i} dependent on N and on the reference potentials.

### TECHNICAL FIELD

This invention relates to a method for determining electrical potentials applied to the phases of a motor comprising several phases in order to avoid generating perturbations in the mechanical torque provided by the motor.

### PRIOR ART

Electric motors are converters of power between the electric domain and the mechanical domain. Mechanical operating points, such as speed and mechanical torque, correspond to electrical operating points, such as voltage, current, or phase difference between current and voltage. Restrictions on the electrical system will be transferred to the mechanical domain, delimiting a region of points of accessible operation.

A polyphase electric machine with N sinusoidal symmetrical phases, N being an integer greater than or equal to 4, has the property of being modellable by three subsystems:
a main system u_{commande} of dimension 2 which is the system to be controlled to produce the electromagnetic torque;
a secondary system u_{secondaire} of dimension N−3 which is a passive system not producing any torque, but which can provide an additional current; and
a homopolar system or component uₕₒₘₒₚₒₗₐᵢᵣₑ of dimension 1 which does not functionally interact with the main system.

This type of machine is supplied with power by N electrical potentials. It is possible to define a transformation matrix T making it possible to relate these N potentials to the three subsystems. This matrix T is defined by the following properties:
the odd columns 1 to 2 [(N−1)/2] written 2k−1 (k varying from 1 to [(N−1)/2]), correspond to the vector having as i-th component (with i varying from 1 to N): c(i, 2k−1)=cos(2πk(i−1)/N);
the even columns 1 to 2 [(N−1)/2] written 2k (k varying from 1 to [(N−1)/2]) correspond to the vector having as i-th component (with i varying from 1 to N): c(i, 2k)=sin(2πk(i−1)/N);
if N is odd, the column N is defined by a constant vector with the value 1/√2;
if N is even, the column N−1 is defined by a vector of alternate constants of value 1/√2 and of value −1/√2 and the column N is defined by a constant vector with the value 1/√2.

Thus, the N potentials of the polyphase electric machine, and therefore of the electric motor with N phases, are related to the three vectors by the relationship:

$$( \begin{matrix}{V}_{1} \\ ⋮ \\ {V}_{N}\end{matrix} ) = T ( \begin{matrix}{u}_{commande} \\ {u}_{secondaire} \\ {u}_{homopoliare}\end{matrix} )$$

with V₁, . . . , V_{N} the N potentials of the motor.

If the components that do not produce any torque are ignored, the N potentials of the motor can be written:

$$( \begin{matrix}{V}_{1} \\ ⋮ \\ {V}_{N}\end{matrix} ) = {Qu}_{commande}$$

with Q a matrix comprising the two first columns of the matrix T.

The motor is controlled by an electric controller that computes drive voltages in response to a speed or torque requirement. These are then transformed into reference potentials, considering the direct approach and the transformation by the matrix Q. The electric controller produces, by way of a power converter, electrical potentials at each phase of the motor, so that it can provide a mechanical torque at a given electrical speed. The voltages across the terminals of the motor windings, which result from the potential differences between the phases, must be sinusoidal and of the largest amplitude possible to achieve a maximum of operating points while having a harmonic content which is of zero or as low as possible, in order to avoid generating perturbations in the mechanical torque in a working frequency range.

The potentials produced by the controller are limited to values between −V_{DC}/2 and +V_{DC}/2, with V_{DC} the voltage of the electrical power supply of the motor, the motor being supplied by said supply by way of a power converter. To avoid any harmonics appearing, it is common to produce sinusoidal potentials which, by construction, are compelled to be less than V_{DC}/2. The sinusoidal voltage across the terminals of the motor windings (arising from the potential differences between the phases of the motor) is thus limited to being less than or equal to V_{DC}/2.

However, for certain values of angle, it would be beneficial to be able to increase the electrical potentials applied to the phases of the motor in order to increase the sinusoidal voltage across the terminals of the motor windings to expand the operating region while keeping potentials to be produced for each phase between −V_{DC}/2 and +V_{DC}/2.

It is therefore desirable to have access to a new method for determining electrical potentials provided to the phases of a motor, in such a way as to expand the operating region without generating any harmonics and perturbation in the mechanical torque provided by the motor.

### SUMMARY OF THE INVENTION

This invention relates to a method for determining electrical potentials to be produced across the terminals of the phases of a motor comprising N phases, N being an integer greater than or equal to 4, the method comprising the following steps:
defining a drive voltage of amplitude V_{MAG} and of phase θ which is less than a limit voltage;
determining reference electrical potentials across the terminals of the N phases of the motor for this drive voltage with

$${V}_{REF \_ i} = {V}_{MAG} cos ( θ - \frac{2 π}{N} ( i - 1 ) )$$

where i is between 1 and N, V_{REF_i} is the reference electrical potential across the terminals of the i-th phase and θ is the phase of the drive voltage between 0 and 2π;
comparing the reference electrical potentials to a first threshold;
if the reference electrical potentials are all less than or equal to the first threshold, then the electrical potentials to be produced across the terminals of the N phases of the motor are equal to the reference electrical potentials, or if at least one of the reference electrical potentials is greater than the first threshold, comparing these reference electrical potentials to a second threshold, the second threshold being greater than the first threshold;
if these reference electrical potentials are all less than or equal to the second threshold, then the electrical potentials to be produced across the terminals of the N phases of the motor are equal to Vᵢ=V_{REF_i}+V_{H}, with

$${V}_{H} = \frac{{max}_{k = 1 … N} ( {V}_{{REF}_{k}} ) + {min}_{k = 1 … N} ( {V}_{{REF}_{k}} )}{2}$$

or if at least one of the reference potentials is greater than the second threshold, then the potentials to be produced across the terminals of the N phases of the motor are equal to Vᵢ=V_{REF_i}+V_{S_i}+V_{HN}, with V_{HN} a homopolar potential dependent on the number of phases and on the reference electrical potentials and V_{S_i} a secondary potential dependent on the number of phases and on the reference electrical potentials.

According to a particular feature of the invention, the secondary V_{S_i} and homopolar V_{HN} potentials are expressed by the following functions:

$$( \begin{matrix}{V}_{{S}_{1}} \\ ⋮ \\ {V}_{{S}_{N}}\end{matrix} ) = T ( : , 3 : N - 1 ) ( \begin{matrix}{V}_{{SAB}_{1}} \\ ⋮ \\ {V}_{{SAB}_{N - 1}}\end{matrix} )$$

with
if N is odd, with p=(N−1)/2:

$${V}_{SABi} ( k ) = \frac{\begin{matrix}[ U ( k + 2 ) V ( 2 ) - U ( 2 ) V ( k + 2 ) ] \\ [ V ( k + 2 ) U ( 1 ) - V ( 1 ) U ( k + 2 ) ]\end{matrix}}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$

$$with k ranging from 1 to N - 3 , and$$

$${V}_{HN} = \frac{1}{\sqrt{2}} \frac{\begin{matrix}[ U ( N ) V ( 2 ) - U ( 2 ) V ( N ) ] \\ [ V ( N ) U ( 1 ) - V ( 1 ) U ( N ) ]\end{matrix}}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$

U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference electrical potentials;
iN the p indices of the p smallest values of the reference electrical potentials;
iM the index of the median value of the reference electrical potentials;
i varying from 1 to N, and
T a transformation matrix defined by:
   the odd columns from 1 to 2 [(N−1)/2] written 2k−1 (k varying from 1 to [(N−1)/2]), correspond to the vector having as i-th component (with i varying from 1 to N): c(i, 2k−1) =cos(2πk(i−1)/N);
   the even columns from 1 to 2 [(N−1)/2] written 2k (k varying from 1 to [(N−1)/2]) correspond to the vector having as i-th component (with i varying from 1 to N): c(i, 2k)=sin (2πk(i−1)/N);
   if N is odd, the column N is defined by a constant vector with the value 1/√2;
   if N is even, the column N−1 is defined by a vector of alternate constants of value 1/√2 and of value −1/√2 and the column N is defined by a constant vector with the value 1/√2,
If N is even, with p=N/2: V_{H}=0 and V_{SAB_i}(k) is defined by:
   If k varies from 1 to p−2:

$${V}_{SABi} ( 2 + k + 2 ⌊ ( k - 1 ) / 2 ⌋ ) = {Q}^{- 1} \cdot ( \begin{matrix}{V}_{M} - {V}_{REF iP ( 1 )} \\ ⋮ \\ {V}_{M} - {V}_{REF iP ( p - 2 )}\end{matrix} )$$

For other values of k between 1 and N−3: V_{SAB_i}(k)=0;
   with

$${V}_{M} = - \frac{{V}_{{REF}_{iP ( p - 1 )}} - {p}_{M} ( \begin{matrix}{V}_{REF \_ iP ( 1 )} \\ ⋮ \\ {V}_{REF \_ iP ( p - 2 )}\end{matrix} )}{1 - {p}_{M} ( \begin{matrix}1 \\ ⋮ \\ 1\end{matrix} )}$$

p_{M}=qQ⁻¹;
iP the p−1 indices of the p−1 greatest values of the reference electrical potentials for i varying from 1 to N;
q the row vector formed of the elements of the row of the transformation matrix T corresponding to the last index of iP corresponding to the columns indexed

$$4 + k + 2 ⌊ \frac{k - 1}{2} ⌋$$

where k varies from 1 to p−2; and
Q the matrix formed of the elements of the transformation matrix T at the intersection of the rows corresponding to the p−2 first indices of the iP and of the columns indexed

$$4 + k + 2 ⌊ \frac{k - 1}{2} ⌋$$

where k varies from 1 to p−2.

The addition of the component V_{H} or V_{HN}, known as the homopolar potential, and/or of the component V_{S_i}, known as the secondary potential, to the reference electrical potentials V_{REF_i} across the terminals of the phases of the motor thus makes it possible to increase the limit of the drive voltage on each phase of the polyphase electric motor, while keeping potentials to be produced across the terminals of each phase between −V_{DC}/2 and +V_{DC}/2. One thus obtains the ability to have an amplitude of sinusoidal voltage cross the terminals of the motor windings greater than V_{DC}/2 and less than the limit voltage V_{LIM}. This makes it possible to expand the operating region of the motor without generating any harmonics and therefore to limit the perturbations in the mechanical torque provided by the motor.

According to another particular feature of the invention, the limit voltage and the second threshold are functions dependent on the number of phases of the motor and on the electrical potential V_{DC} of an electrical power supply of the motor.

This makes it possible to define the second threshold and the limit voltage directly as a function of the number of phases of the motor and of the electrical supply potential. One can thus determine above which threshold a secondary potential must be added to the reference electrical potentials determined in the method to be able to reach the limit voltage without generating any harmonics.

According to another particular feature of the invention, the first threshold is a function dependent on the electrical potential of the electrical power supply of the motor.

This makes it possible to define the first threshold directly as a function of the electrical potential of the electrical power supply of the motor.

According to another particular feature of the invention, the second threshold is expressed by the following function:

$$seuil 2 = \frac{{V}_{D C}}{2} \frac{1}{sin ( \frac{π}{N} + \frac{π}{N} \cdot ⌊ \frac{N}{2} ⌋ )}$$

According to another particular feature of the invention, the limit voltage is expressed by the following function:

$${V}_{LIM} = \frac{{V}_{D C}}{2} \frac{2}{N} cos ( α ) {\sum }_{j = 0}^{N - 1} \vert cos ( \frac{2 π}{N} j ) \vert$$

with α=π/(2N) if N is odd or α=0 if N is even and a multiple of 4 or α=π/N if N is even and a non-multiple of 4.

This function makes it possible to determine the value of the maximum possible limit voltage V_{LIM} for a given number of phases N, and thus the maximum amplitude of the sinusoidal voltage across the terminals of the motor windings. Thus, if the motor comprises 3 phases, the maximum limit voltage will be 115% of V_{DC}/2, or if the motor comprises 4 phases, it will be 100% of V_{DC}/2. This therefore makes it possible to know what the maximum amplitude of the sinusoidal voltage across the terminals of the motor can be, while keeping, for each phase, potentials to be produced between −V_{DC}/2 and +V_{DC}/2.

According to another particular feature of the invention, the first threshold is equal to V_{DC}/2.

According to another particular feature of the invention, the motor is a five-phase motor, N is equal to 5, the first threshold is equal to V_{DC}/2, the second threshold is equal to 1.05×V_{DC}/2 and the limit voltage V_{LIM} is equal to 1.23×V_{DC}/2, with V_{DC} the electrical potential of the electrical power supply of the power converter, and if at least one of the reference electrical potentials is greater than the second threshold, then the electrical potentials to be produced across the terminals of the 5 phases of the motor are equal to Vᵢ₍ᵢ₌ₚ₎=V_{M} for p, such that the reference electrical potentials V_{REF_p} are the two largest reference electrical potentials; Vᵢ₍ᵢ₌ₗ₎=−V_{M} for l, such that the reference electrical potentials V_{REF_l} are the two smallest reference electrical potentials; or Vᵢ₍ᵢ₌ⱼ₎=V_{C} for j, such that the reference electrical potential V_{REF_j} is the median reference electrical potential, with

$${V}_{M} = \frac{3 \sqrt{5} - 5}{4} ( {max}_{k = 1 … 5} ( {V}_{REF k} ) - {min}_{k = 1 … 5} ( {V}_{REF k} ) ) .$$

$$and$$

$${V}_{C} = \frac{5}{2} {median}_{k = 1 … 5} ( {V}_{REF k} )$$

with p, j and l chosen from among {1; 2; 3; 4; 5} and p≠j≠l.

Another subject of the invention is an electric controller intended to be connected to a motor with N phases and to an electrical power supply source, with N an integer greater than or equal to 4, the controller being configured to:
define a drive voltage of amplitude V_{MAG} and of phase θ which is less than a limit voltage;
determine reference electrical potentials across the terminals of the N phases of the motor for the drive voltage with

$${V}_{REF \_ i} = {V}_{MAG} cos ( θ - \frac{2 π}{N} ( i - 1 ) )$$

where i is between 1 and N, V_{REF_i} is the reference electrical potential across the terminals of the i-th phase and θ is the phase of the drive voltage between 0 and 2π;
compare the reference electrical potentials to a first threshold;
if the reference electrical potentials are all less than or equal to the first threshold, then the electrical potentials to be produced across the terminals of the N phases of the motor are equal to the reference electrical potentials, or if at least one of the reference electrical potentials is greater than the first threshold, compare these reference electrical potentials to a second threshold, the second threshold being greater than the first threshold;
if these reference electrical potentials are all less than or equal to the second threshold, then the electrical potentials to be produced across the terminals of the N phases of the motor are equal to Vᵢ=V_{REF_i}+V_{H}, with

$${V}_{H} = \frac{{max}_{k = 1 … N} ( {V}_{{REF}_{k}} ) + {min}_{k = 1 … N} ( {V}_{{REF}_{k}} )}{2}$$

or if at least one of the reference potentials is greater than the second threshold, then the potentials to be produced across the terminals of the N phases of the motor are equal to Vᵢ=V_{REF_i}+V_{S_i}+V_{HN}, with V_{HN} a homopolar potential dependent on the number of phases and on the reference electrical potentials and V_{S_i} a secondary potential dependent on the number of phases and on the reference electrical potentials.

According to a particular feature of the invention, the secondary V_{S_i} and homopolar V_{H} potentials are expressed by the following functions:

$$( \begin{matrix}\begin{matrix}{V}_{{S}_{1}} \\ ⋮\end{matrix} \\ {V}_{{S}_{N}}\end{matrix} ) = T ( : , 3 : N - 1 ) ( \begin{matrix}\begin{matrix}{V}_{{SAB}_{1}} \\ ⋮\end{matrix} \\ {V}_{{SAB}_{N - 3}}\end{matrix} )$$

with:
if N is odd, with p=(N−1)/2:

$${V}_{SABI} ( k ) = \frac{[ U ( k + 2 ) V ( 2 ) - U ( 2 ) V ( k + 2 ) ] [ V ( k + 2 ) U ( 1 ) - V ( 1 ) U ( k + 2 ) ]}{U ( 1 ) V ( 2 ) - U ( 2 ) V ( 1 )} {T}^{- 1} ( 1 : 2 , : ) ( \begin{matrix}\begin{matrix}{V}_{REF \_ 1} \\ ⋮\end{matrix} \\ {V}_{REF \_ N}\end{matrix} )$$

with k ranging from 1 to N−3, and

$${V}_{HN} = \frac{1}{\sqrt{2}} \frac{[ U ( N ) V ( 2 ) - U ( 2 ) V ( N ) ] [ V ( N ) U ( 1 ) - V ( 1 ) U ( N ) ]}{U ( 1 ) V ( 2 ) - U ( 2 ) V ( 1 )} {T}^{- 1} ( 1 : 2 , : ) ( \begin{matrix}\begin{matrix}{V}_{REF \_ 1} \\ ⋮\end{matrix} \\ {V}_{REF \_ N}\end{matrix} )$$

U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference electrical potentials;
iN the p indices of the p smallest values of the reference electrical potentials;
iM the index of the median value of the reference electrical potentials;
i varying from 1 to N, and
T a transformation matrix defined by:
   the odd columns from 1 to 2 [(N−1)/2] written 2k−1 (k varying from 1 to [(N−1)/2]), correspond to the vector having as i-th component (with i varying from 1 to N): c(i, 2k−1) =cos (2πk(i−1)/N);
   the even columns from 1 to 2 [(N−1)/2 ] written 2k (k varying from 1 to [(N−1)/2]) correspond to the vector having as i-th component (with i varying from 1 to N): c(i, 2k)=sin(2πk(i−1)/N);
   if N is odd, the column N is defined by a constant vector with the value 1/√2;
   if N is even, the column N−1 is defined by a vector of alternate constants of value 1/√2 and of value −1/√2 and the column N is defined by a constant vector with the value 1/√2.
If N is even, with p=N/2: V_{H}=0 and V_{SAB_i}(k) is defined by:
   If k varies from 1 to p−2:

$${V}_{SABi} ( 2 + k - 2 ⌊ ( k - 1 ) / 2 ⌋ ) = {Q}^{- 1} \cdot ( \begin{matrix}\begin{matrix}{V}_{M} - {V}_{REF iP ( 1 )} \\ ⋮\end{matrix} \\ {V}_{M} - {V}_{REF iP ( p - 2 )}\end{matrix} )$$

For other values of k between 1 and N−3: V_{SAB_i}(k)=0;
   with

$${V}_{M} = - \frac{{V}_{{REF}_{iP ( p - 1 )}} - {p}_{M} ( \begin{matrix}\begin{matrix}{V}_{REF \_ iP ( 1 )} \\ ⋮\end{matrix} \\ {V}_{REF \_ iP ( p - 2 )}\end{matrix} )}{1 - {p}_{M} ( \begin{matrix}\begin{matrix}1 \\ ⋮\end{matrix} \\ 1\end{matrix} )}$$

$${p}_{M} = {qQ}^{- 1} ;$$

iP the p−1 indices of the p−1 greatest values of the reference electrical potentials for i varying from 1 to N;
q the row vector formed of the elements of the row of the transformation matrix T corresponding to the last index of iP corresponding to the columns indexed

$$4 + k + 2 ⌊ \frac{k - 1}{2} ⌋$$

where k varies from 1 to p−2; and
Q the matrix formed of the elements of the transformation matrix T at the intersection of the rows corresponding to the p−2 first indices of the iP and of the columns indexed

$$4 + k + 2 ⌊ \frac{k - 1}{2} ⌋$$

where k varies from 1 to p−2.

The controller of the invention makes it possible to provide the electrical potentials across the terminals of the N phases of the motor to increase the operating region of the motor by modifying the potentials of the phases to obtain a sinusoidal voltage across the terminals of the motor windings of a maximum amplitude equal to the limit voltage, while keeping potentials to be produced across the terminals of each phase of the motor between −V_{DC}/2 and +V_{DC}/2.

According to another particular feature of the invention, the limit voltage and the second threshold are functions dependent on the number of phases of the motor and on the electrical potential of the electrical power supply intended to be connected to the electric controller.

According to another particular feature of the invention, the second threshold is expressed by the following function:

$$seuil 2 = \frac{{V}_{DC}}{2} \frac{1}{sin ( \frac{π}{N} + \frac{π}{N} \cdot ⌊ \frac{N}{2} ⌋ )}$$

with V_{DC} the voltage of the electrical power supply intended to be connected to the electric controller and N the number of phases of the motor intended to be connected to the electric controller.

According to another particular feature of the invention, the limit voltage is expressed by the following function:

$${V}_{LIM} - \frac{{V}_{DC}}{2} \frac{2}{N} cos ( α ) {\sum }_{j = 0}^{N - 1} \vert cos ( \frac{2 π}{N} j ) \vert$$

with α=π/(2N) if N is odd or α=0 if N is even and a multiple of 4 or α=π/N if N is even and a non-multiple of 4, and with V_{DC} the voltage of the electrical power supply intended to be connected to the electric controller and N the number of phases of the motor intended to be connected to the electric controller.

Yet another subject of the invention is an electric device comprising:
an electrical power supply source;
an electric controller according to the invention, an input of which is connected to the electrical power supply source;
a power converter, inputs of which are connected to the electric controller, and
a motor with N phases connected to the power converter,
   N being an integer greater than or equal to 4, and the power converter being configured to provide electrical potentials as input to the N phases of the motor.

### BRIEF DESCRIPTION OF THE DRAWINGS

Other features and advantages of this invention will become apparent from the description given below, with reference to the appended drawings which illustrate exemplary embodiments thereof without any limitation.

FIG. 1 represents, schematically and partially, a flowchart of the method for determining electrical potentials to be produced across the terminals of the phases of a motor with several phases according to an embodiment of the invention.

FIG. 2A represents the reference electrical potential V_{REF_i} across the terminals of the five phases of a five-phase motor before the application of the method of the invention for a drive voltage V_{MAG} of amplitude equal to 90% of V_{DC}/2.

FIG. 2B represents the reference electrical potential V_{REF_i} across the terminals of the five phases of a five-phase motor before the application of the method of the invention, and the homopolar potential V_{H} as described in the method of the invention for a drive voltage V_{MAG} of amplitude equal to 100% of V_{DC}/2.

FIG. 2C represents the reference electrical potential V_{REF_i} across the terminals of the five phases of a five-phase motor before the application of the method of the invention, and the electrical potential to be produced Vᵢ across the terminals of the five phases of the motor after the application of the method of the invention, as well as the possible values of the homopolar potential V_{H} for a drive voltage V_{MAG} of amplitude equal to 105% of V_{DC}/2.

FIG. 3A represents the reference electrical potential V_{REF_i} across the terminals of the five phases of a five-phase motor before the application of the method of the invention, and the electrical potential to be produced Vᵢ across the terminals of the five phases of the motor after the application of the method of the invention, as well as the possible values of the homopolar potential V_{HN} and of the components V_{SAB_i} of the secondary potential V_{S_i} for a drive voltage V_{MAG} of amplitude equal to 110% of V_{DC}/2.

FIG. 3B represents the reference electrical potential V_{REF_i} across the terminals of the five phases of a five-phase motor before the application of the method of the invention, and the electrical potential to be produced Vᵢ across the terminals of the five phases of the motor after the application of the method of the invention, as well as the possible values of the homopolar potential V_{HN} and of the components V_{SAB_i} of the secondary potential V_{S_i} for a drive voltage V_{MAG} of amplitude equal to 123% of V_{DC}/2, i.e. equal to the limit voltage V_{LIM}.

FIG. 4 represents, schematically and partially, an electric device according to an embodiment of the invention.

FIG. 5A represents the reference electrical potential V_{REF_i} across the terminals of the six phases of a six-phase motor before the application of the method of the invention for a drive voltage V_{MAG} of amplitude equal to 90% of V_{DC}/2.

FIG. 5B represents the reference electrical potential V_{REF_i} across the terminals of the six phases of a six-phase motor before the application of the method of the invention, and the electrical potential to be produced Vᵢ across the terminals of the six phases of the motor after the application of the method of the invention, as well as the possible values of the component V_{SAB_i} (3) of the secondary potential V_{S_i} for a drive voltage V_{MAG} of amplitude equal to 105% of V_{DC}/2.

FIG. 5C represents the reference electrical potential V_{REF_i} across the terminals of the six phases of a six-phase motor before the application of the method of the invention, and the electrical potential to be produced Vᵢ across the terminals of the six phases of the motor after the application of the method of the invention, as well as the possible values of the component V_{SAB_i}(3) of the secondary potential V_{S_i} for a drive voltage V_{MAG} of amplitude equal to 115.7% of V_{DC}/2.

### DESCRIPTION OF THE EMBODIMENTS

In the remainder of the description, in order to simplify the writing, the terms “reference electrical potential of a phase” or “electrical potential to be produced of a phase” will be used to refer to the reference electrical potential across the terminals of the phase or the electrical potential to be produced across the terminals of the phase.

The term “potential” is also used to refer to an “electrical potential”.

In the remainder of the description, V_{DC} denotes the voltage of the electrical power supply of the motor, the motor being supplied with power by this electrical power supply by way of a power converter.

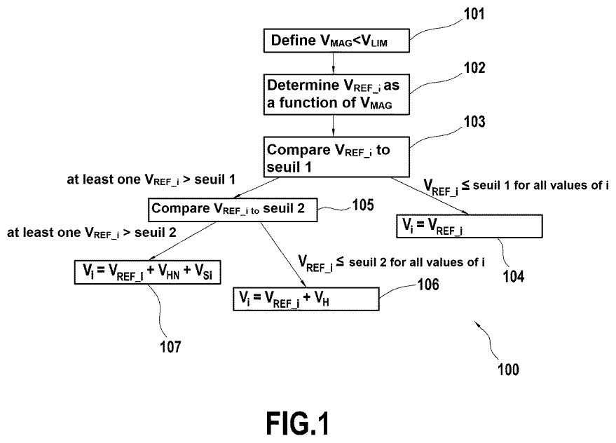

FIG. 1 shows a flowchart of the method 100 for determining the potentials to be produced Vᵢ of the phases of a motor with N phases, N being an integer greater than or equal to 4 and k being between 1 and N.

The method 100 comprises the defining 101 of a drive voltage V_{MAG} which is less than a limit voltage V_{LIM} and also the determining 102 of the reference potentials V_{REF_i} of the N phases of the motor based on the drive voltage V_{MAG}, i being an integer between 1 and N and V_{REF_i} representing the reference potential of the i-th phase of the motor.

The reference potentials V_{REF_i} of the N phases are expressed by the following formula:

$${V}_{REF \_ i} = {V}_{MAG} cos ( θ - \frac{2 π}{N} ( i - 1 ) )$$

with θ the phase of the drive voltage between 0 and 2π.

The limit voltage Vum represents the maximum amplitude desired for the drive voltage V_{MAG} across the terminals of the motor windings, while keeping potentials to be produced between −V_{DC}/2 and +V_{DC}/2 for the N phases.

It can be defined by a user and vary between 0 and +V_{DC}/2.

It can also be a function dependent on the potential V_{DC} of the electrical power supply of the motor: for example, it can be equal to a fraction of V_{DC}, for example 80×V_{DC}/100 or 110×V_{DC}/100. It can also be a function dependent on the potential V_{DC} and on the number of phases N in the motor.

Advantageously, the limit voltage V_{LIM} is expressed by the following function, as a function of the number of phases N of the motor and of the supply potential of the motor V_{DC}:

$${V}_{LIM} - \frac{{V}_{DC}}{2} \frac{2}{N} cos ( α ) {\sum }_{j = 0}^{N - 1} \vert cos ( \frac{2 π}{N} j ) \vert$$

with α=π/(2N) if N is odd or α=0 if N is even and a multiple of 4 or α=π/N if N is even and a non-multiple of 4.

These functions dependent on N make it possible to determine the limit voltage V_{LIM}, and therefore the maximum amplitude of the drive voltage V_{MAG} for a given number of phases N.

The method 100 then comprises the comparing 103 of the reference potentials V_{REF_i} determined during the step 102 to a first threshold. The first threshold can be a potential value chosen by the user or a function

dependent on the potential of the power supply of the motor V_{DC}. For example, the first threshold may be chosen equal to 0.8×V_{DC}/2 or to V_{DC}/2. Preferably, the first threshold is equal to V_{DC}/2.

If the reference potentials V_{REF_i} are all less than or equal to the first threshold whatever the value of i (step 104), then the potentials to be produced Vᵢ of the N phases of the motor are equal to the reference potentials V_{REF_i} determined in the step 102.

If at least one of the reference potentials V_{REF_i} determined in the step 102 is greater than the first threshold, then the method comprises the comparing 105 of the reference potentials V_{REF_i} to a second threshold greater than the first threshold.

The second threshold can be a potential value chosen by the user or a function dependent on the potential of the power supply of the motor V_{DC} or else a function dependent on the number of phases N of the motor and on the potential of the power supply of the motor V_{DC}. For example, the second threshold may be chosen equal to 1.1×V_{DC}/2.

Advantageously, the second threshold is expressed by the following function, as a function of the number of phases N of the motor and of the power supply potential of the motor V_{DC}:

$$seuil 2 = \frac{{V}_{DC}}{2} \frac{1}{sin ( \frac{π}{N} + \frac{π}{N} \cdot ⌊ \frac{N}{2} ⌋ )}$$

When the limit voltage V_{LIM} is chosen by the user between 0 and +V_{DC}/2, it can more specifically be chosen as being equal to the first threshold or to the second threshold.

Following this comparison 105, if the reference potentials V_{REF_i} are all less than or equal to the second threshold whatever the value of i (step 106), then the potentials to be produced Vᵢ of the N phases of the motor are equal to Vᵢ=V_{REF_i}+V_{H}, with V_{H} a homopolar potential expressed by the following formula:

$${V}_{H} = \frac{{max}_{k = 1 … N} ( {V}_{{REF}_{k}} ) + {min}_{k = 1 … N} ( {V}_{{REF}_{k}} )}{2}$$

where

$${max}_{k = 1 ... N} {V}_{{REF}_{k}}$$

denotes the maximum potential from among the reference potentials V_{REF_i} determined in the step 102, and

$${max}_{k = 1 ... N} {V}_{{REF}_{k}}$$

refers to the minimum potential from among the reference potentials V_{REF_i} determined in the step 102.

If at least one of the reference potentials V_{REF_i} is greater than the second threshold, then the potentials to be produced Vᵢ of the N phases of the motor are equal to Vᵢ=V_{REF_i}+V_{S_i}+V_{HN}, with V_{HN} a homopolar potential dependent on the number of phases N and on the reference electrical potentials V_{REF_i} and V_{S_i} a secondary potential dependent on the number of phases N and on the reference electrical potentials V_{REF_i}.

In this scenario, the secondary V_{S_i} and homopolar V_{HN} potentials can be expressed by the following functions:

$$( \begin{matrix}{V}_{{S}_{1}} \\ ⋮ \\ {V}_{{S}_{N}}\end{matrix} ) = T ( : , 3 : N - 1 ) ( \begin{matrix}{V}_{{SAB}_{1}} \\ ⋮ \\ {V}_{{SAB}_{N - 2}}\end{matrix} )$$

with:
if N is odd, with p=(N−1)/2:

$${V}_{SABi} ( k ) = \frac{\begin{matrix}[ U ( k + 2 ) V ( 2 ) - U ( 2 ) V ( k + 2 ) ] \\ [ V ( k + 2 ) U ( 1 ) - V ( 1 ) U ( k + 2 ) ]\end{matrix}}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$

$$k ranging from 1 to N - 3 , and$$

$${V}_{HN} = \frac{1}{\sqrt{2}} \frac{\begin{matrix}[ U ( N ) V ( 2 ) - U ( 2 ) V ( N ) ] \\ [ V ( N ) U ( 1 ) - V ( 1 ) U ( N ) ]\end{matrix}}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$

with:
U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference potentials V_{REF_i};
iN the p indices of the p smallest values of the reference potentials V_{REF_i};
iM the index of the median value of the reference potentials V_{REF_i};
i varying from 1 to N, and
T a transformation matrix defined by:
   the odd columns from 1 to 2 [(N−1)/2] written 2k−1 (k varying from 1 to [(N−1)/2]), correspond to the vector having as i-th component (with i varying from 1 to N): c(i, 2k−1)=cos(2πk(i−1)/N);
   the even columns from 1 to 2[(N−1)/2] written 2k (k varying from 1 to [(N−1)/2]) correspond to the vector having as i-th component (with i varying from 1 to N): c(i, 2k)=sin(2πk(i−1)/N);
   if N is odd, the column N is defined by a constant vector with the value 1/√2;
   if N is even, the column N−1 is defined by a vector of alternate constants of value 1/√2 and of value −1/√2 and the column N is defined by a constant vector with the value 1/√2.
If N is even, with p=N/2: V_{H}=0 and V_{SAB_i}(k) is defined by:
   If k varies from 1 to p−2:

$${V}_{SABi} ( 2 + k + 2 ⌊ ( k - 1 ) / 2 ⌋ ) = {Q}^{- 1} \cdot ( \begin{matrix}{V}_{M} - {V}_{REF iP ( 1 )} \\ ⋮ \\ {V}_{M} - {V}_{REF iP ( p - 2 )}\end{matrix} )$$

For other values of k between 1 and N−3: V_{SAB_i}(k)=0;
   with

$${V}_{M} = \frac{{V}_{{REF}_{iP ( p - 1 )}} - {p}_{M} ( \begin{matrix}{V}_{REF \_ iP ( 1 )} \\ ⋮ \\ {V}_{REF \_ iP ( p - 2 )}\end{matrix} )}{1 - {p}_{M} ( \begin{matrix}1 \\ ⋮ \\ 1\end{matrix} )}$$

$${p}_{M} = {qQ}^{- 1} ;$$

iP the p−1 indices of the p−1 greatest values of the reference potentials V_{REF_i} for i varying from 1 to N;
q the row vector formed of the elements of the row of the transformation matrix T corresponding to the last index of iP corresponding to the columns indexed

$$4 + k + 2 ⌊ \frac{k - 1}{2} ⌋$$

where k varies from 1 to p−2; and
Q the matrix formed of the elements of the transformation matrix T at the intersection of the rows corresponding to the p−2 first indices of the iP and of the columns indexed

$$4 + k + 2 ⌊ \frac{k - 1}{2} ⌋$$

where k varies from 1 to p−2.

Thus the electrical potentials to be produced Vᵢ determined by the method 100 may comprise a homopolar potential and/or a secondary potential according to the values of the reference potentials V_{REF_i} with respect to the first and second thresholds.

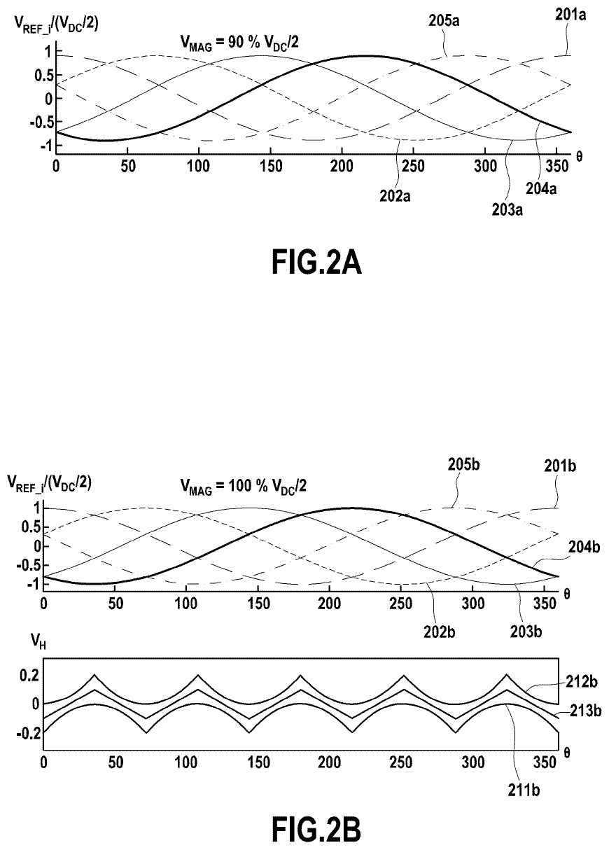

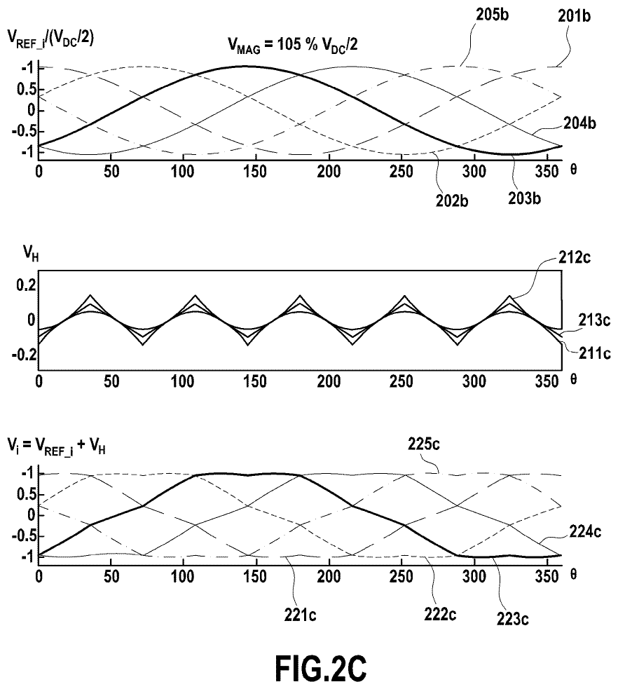

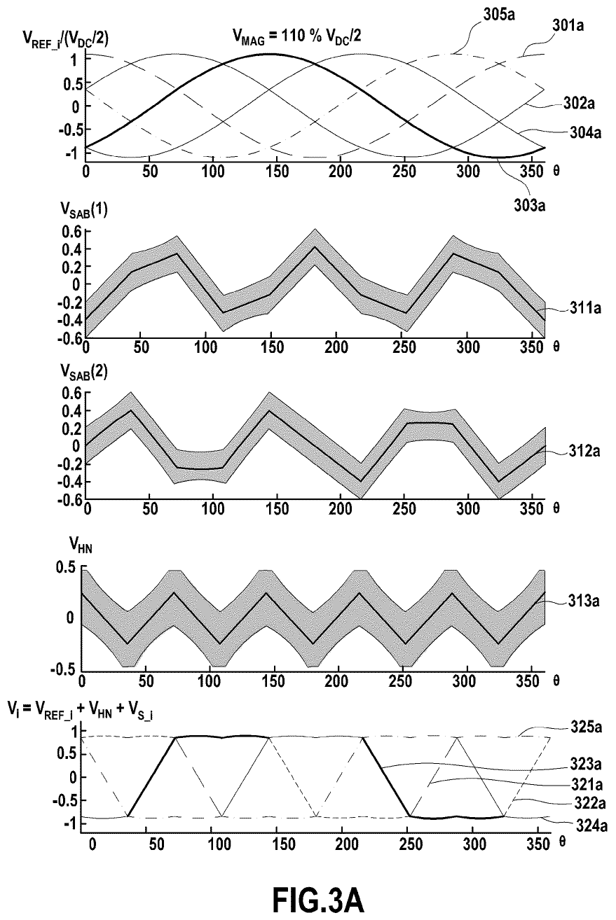

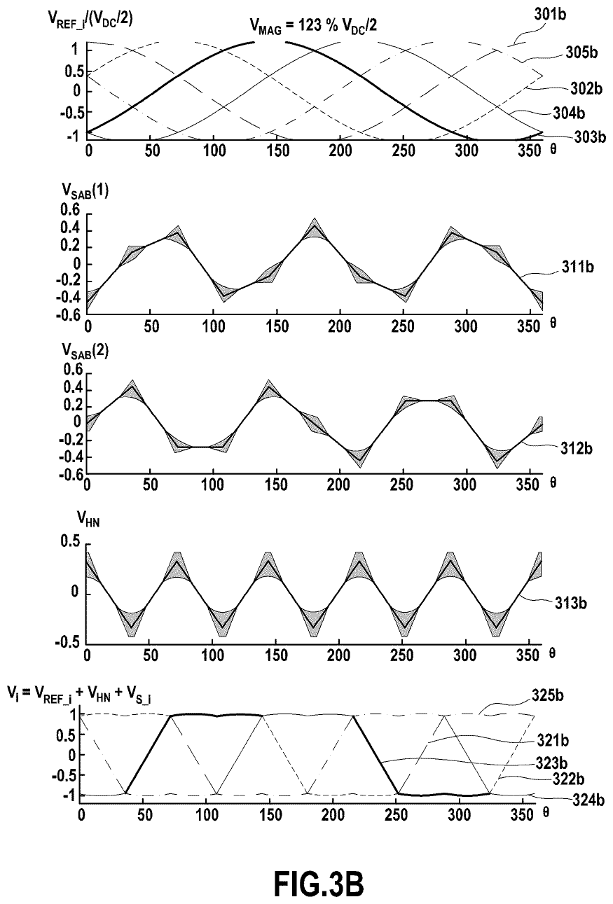

FIGS. 2A, 2B, 2C, 3A and 3B show an implementation of the method of the invention for a five-phase motor, so for N=5.

Thus, by applying the formulae proposed for the limit voltage V_{LIM} and for the second threshold, the second threshold is equal to 1.05×V_{DC}/2 and the limit voltage V_{LIM} is equal to 1.23×V_{DC}/2. In this example, the first threshold is equal to V_{DC}/2. The drive voltage V_{MAG} must therefore remain less than or equal to 1.23 x V_{DC}/2.

In addition, if at least one of the reference potentials V_{REF_i} determined in the step 102 is greater than the second threshold, then the potentials to be produced Vᵢ become:
Vᵢ₍ᵢ₌ₚ₎=V_{M} for p such that the reference potentials V_{REF_p} determined in the step 102 are the two largest potentials;
Vᵢ₍ᵢ₌ₗ₎=−V_{M} for l such that the reference potentials V_{REF_l} determined in the step 102 are the two smallest potentials; and
Vᵢ₍ᵢ₌ⱼ₎=V_{C} for j such that the reference potential V_{REF_j} determined in the step 102 is the median potential,
   with p≠l≠j and p, l and j chosen from among {1; 2; 3; 4; 5}; and V_{M} and V_{C} expressed by the following functions:

$${V}_{M} = \frac{3 \sqrt{5} - 5}{4} ( {max}_{k = 1 … 5} ( {V}_{REFk} ) - {min}_{k = 1 … 5} ( {V}_{REF k} ) )$$

$$and$$

$${V}_{C} = \frac{5}{2} {median}_{k = 1 … 5} ( {V}_{REF k} )$$

Specifically, for a five-phase motor, the transformation matrix T is expressed as follows:

$$T = ( \begin{matrix}cos ( \frac{2 π}{5} \cdot 0 ) & sin ( \frac{2 π}{5} \cdot 0 ) & cos ( \frac{4 π}{5} \cdot 0 ) & sin ( \frac{4 π}{5} \cdot 0 ) & \frac{1}{\sqrt{2}} \\ cos ( \frac{2 π}{5} \cdot 1 ) & sin ( \frac{2 π}{5} \cdot 1 ) & cos ( \frac{4 π}{5} \cdot 1 ) & sin ( \frac{4 π}{5} \cdot 1 ) & \frac{1}{\sqrt{2}} \\ cos ( \frac{2 π}{5} \cdot 2 ) & sin ( \frac{2 π}{5} \cdot 2 ) & cos ( \frac{4 π}{5} \cdot 2 ) & sin ( \frac{4 π}{5} \cdot 2 ) & \frac{1}{\sqrt{2}} \\ cos ( \frac{2 π}{5} \cdot 3 ) & sin ( \frac{2 π}{5} \cdot 3 ) & cos ( \frac{4 π}{5} \cdot 3 ) & sin ( \frac{4 π}{5} \cdot 3 ) & \frac{1}{\sqrt{2}} \\ cos ( \frac{2 π}{5} \cdot 4 ) & sin ( \frac{2 π}{5} \cdot 4 ) & cos ( \frac{4 π}{5} \cdot 4 ) & sin ( \frac{4 π}{5} \cdot 4 ) & \frac{1}{\sqrt{2}}\end{matrix} )$$

The homopolar and secondary potentials which are generically expressed as follows:

$${V}_{5 \_ k} = cos ( \frac{4 π}{5} ( k - 1 ) ) {V}_{SAB} ( 1 ) + sin ( \frac{4 π}{5} ( k - 1 ) ) {V}_{SAB} ( 2 )$$

$${V}_{HN} = \frac{1}{5} {V}_{C}$$

$$with :$$

$${V}_{SAB} ( 1 ) = \frac{[ \begin{matrix}( U ( 3 ) V ( 2 ) - U ( 2 ) V ( 3 ) ) & ( V ( 3 ) U ( 1 ) - V ( 1 ) U ( 3 ) )\end{matrix} ]}{U ( 1 ) V ( 2 ) - U ( 2 ) V ( 1 )} {T}^{- 1} ( 1 : 2 , : ) ( \begin{matrix}{V}_{REF \_ 1} \\ {V}_{REF \_ 2} \\ {V}_{REF \_ 3} \\ {V}_{REF \_ 4} \\ {V}_{REF \_ 5}\end{matrix} )$$

$${V}_{SAB} ( 2 ) = \frac{[ \begin{matrix}( U ( 4 ) V ( 2 ) - U ( 2 ) V ( 4 ) ) & ( V ( 4 ) U ( 1 ) - V ( 1 ) U ( 4 ) )\end{matrix} ]}{U ( 1 ) V ( 2 ) - U ( 2 ) V ( 1 )} {T}^{- 1} ( 1 : 2 , : ) ( \begin{matrix}{V}_{REF \_ 1} \\ {V}_{REF \_ 2} \\ {V}_{REF \_ 3} \\ {V}_{REF \_ 4} \\ {V}_{REF \_ 5}\end{matrix} )$$

$${V}_{HN} = \frac{1}{\sqrt{2}} \frac{[ ( U ( 5 ) V ( 2 ) - U ( 2 ) V ( 5 ) ) ( V ( 5 ) U ( 1 ) - V ( 1 ) U ( 5 ) ) ]}{U ( 1 ) V ( 2 ) - U ( 2 ) V ( 1 )} {T}^{- 1} ( 1 : 2 , : ) ( \begin{matrix}{V}_{REF \_ 1} \\ {V}_{REF \_ 2} \\ {V}_{REF \_ 3} \\ {V}_{REF \_ 4} \\ {V}_{REF \_ 5}\end{matrix} )$$

are simplified by setting:

$$W = \frac{[ \begin{matrix}V ( 2 ) & - V ( 1 ) \\ - U ( 2 ) & U ( 1 )\end{matrix} ]}{U ( 1 ) V ( 2 ) - U ( 2 ) V ( 1 )} {T}^{- 1} ( 1 : 2 , : ) ( \begin{matrix}{V}_{REF \_ 1} \\ {V}_{REF \_ 2} \\ {V}_{REF \_ 3} \\ {V}_{REF \_ 4} \\ {V}_{REF \_ 5}\end{matrix} )$$

The homopolar potential and the secondary components of the secondary potential are then expressed by the following formulae:

$${V}_{S A B} ( 1 ) = [ U ( 3 ) V ( 3 ) ] \cdot W$$

$${V}_{S A B} ( 2 ) = [ U ( 4 ) V ( 4 ) ] \cdot W$$

$${V}_{H N} = \frac{1}{\sqrt{2}} [ U ( 5 ) V ( 5 ) ] \cdot W$$

The main system u_{commande} is then written:

$${u}_{commande} ( 1 ) = [ \begin{matrix}U ( 1 ) & V ( 1 )\end{matrix} ] \cdot W$$

$${u}_{commande} ( 2 ) = [ \begin{matrix}U ( 2 ) & V ( 2 )\end{matrix} ] \cdot W$$

The potentials to be produced V₁, V₂, V₃, V₄ and V₅ are therefore written:

$$( \begin{matrix}{V}_{1} \\ {V}_{2} \\ {V}_{3} \\ {V}_{4} \\ {V}_{5}\end{matrix} ) = T ( \begin{matrix}{u}_{commande} ( 1 ) \\ {u}_{commande} ( 2 ) \\ {V}_{SAB} ( 1 ) \\ {V}_{SAB} ( 2 ) \\ \sqrt{2} {V}_{HN}\end{matrix} ) = T \cdot {T}^{- 1} \cdot [ u v ] \cdot W$$

$$i . e .$$

$$( \begin{matrix}{V}_{1} \\ {V}_{2} \\ {V}_{3} \\ {V}_{4} \\ {V}_{5}\end{matrix} ) = \{ \begin{matrix}W ( 1 ) : if i , such that {V}_{REF i} is one of the two largest \\ - W ( 1 ) : if i , such that {V}_{REF i} is one of the two smallest \\ W ( 2 ) : if i , such that {V}_{REF i} is one of the median value\end{matrix}$$

With no loss of generality, by considering that the phase of the drive voltage V_{MAG} varies between 0 and π/5, then the values of the reference potentials V_{REF_i} are ranked from the smallest to the largest in the order 4, 3, 5, 2 and 1. The other scenarios, i.e. for a phase between π/5 and 2π, are obtained by symmetry and permutation of indices.

It therefore comes about that the vectors u, v, U and V are defined by:

$$u = ( \begin{matrix}1 \\ 1 \\ - 1 \\ - 1 \\ 0\end{matrix} )$$

$$v = ( \begin{matrix}0 \\ 0 \\ 0 \\ 0 \\ 1\end{matrix} )$$

$$U = \frac{2}{5} \cdot ( \begin{matrix}1 + cos ( \frac{2 π}{5} ) - cos ( \frac{4 π}{5} ) - cos ( \frac{6 π}{5} ) \\ sin ( \frac{2 π}{5} ) - sin ( \frac{4 π}{5} ) - sin ( \frac{6 π}{5} ) \\ 1 + cos ( \frac{4 π}{5} ) - cos ( \frac{8 π}{5} ) - cos ( \frac{12 π}{5} ) \\ sin ( \frac{4 π}{5} ) - sin ( \frac{8 π}{5} ) - sin ( \frac{12 π}{5} )\end{matrix} )$$

$$V = \frac{2}{5} \cdot ( \begin{matrix}cos ( \frac{8 π}{5} ) \\ sin ( \frac{8 π}{5} ) \\ cos ( \frac{16 π}{5} ) \\ sin ( \frac{16 π}{5} ) \\ \frac{1}{\sqrt{2}}\end{matrix} )$$

By writing:

$${V}_{REF \_ 2} - {V}_{REF \_ 3} = \frac{sin ( \frac{π}{5} )}{sin ( \frac{2 π}{5} )} \cdot ( {V}_{REF \_ 1} - {V}_{REF \_ 4} )$$

$$and$$

$${V}_{REF \_ 2} + {V}_{REF \_ 3} = - \frac{cos ( \frac{π}{5} )}{cos ( \frac{2 π}{5} )} \cdot ( {V}_{REF \_ 1} + {V}_{REF \_ 4} ) = - 2 \cdot cos ( \frac{π}{5} ) \cdot {V}_{REF \_ 5}$$

one obtains the following expressions relating the reference potentials V_{REF_1}, V_{REF_2}, V_{REF_3}, V_{REF_4} and V_{REF_5} to one another:

$${V}_{REF \_ 1} = \frac{{V}_{REF \_ 1} + {V}_{REF \_ 4}}{2} + \frac{{V}_{REF \_ 1} - {V}_{REF \_ 4}}{2} = cos ( \frac{2 π}{5} ) \cdot {V}_{REF \_ 5} + \frac{{V}_{REF \_ 1} - {V}_{REF \_ 4}}{2}$$

$${V}_{REF \_ 4} = \frac{{V}_{REF \_ 1} + {V}_{REF \_ 4}}{2} + \frac{{V}_{REF \_ 1} - {V}_{REF \_ 4}}{2} = cos ( \frac{2 π}{5} ) \cdot {V}_{REF \_ 5} + \frac{{V}_{REF \_ 1} - {V}_{REF \_ 4}}{2}$$

$${V}_{REF \_ 2} = \frac{{V}_{REF \_ 2} + {V}_{REF \_ 3}}{2} + \frac{{V}_{REF \_ 2} - {V}_{REF \_ 3}}{2} = cos ( \frac{π}{5} ) \cdot {V}_{REF \_ 5} + \frac{sin ( \frac{π}{5} )}{sin ( \frac{2 π}{5} )} \frac{{V}_{REF \_ 1} - {V}_{REF \_ 4}}{2}$$

$${V}_{REF \_ 3} = \frac{{V}_{REF \_ 2} + {V}_{REF \_ 3}}{2} + \frac{{V}_{REF \_ 2} - {V}_{REF \_ 3}}{2} = cos ( \frac{π}{5} ) \cdot {V}_{REF \_ 5} + \frac{sin ( \frac{π}{5} )}{sin ( \frac{2 π}{5} )} \frac{{V}_{REF \_ 1} - {V}_{REF \_ 4}}{2}$$

One then computes the vector W which is written in a simplified manner:

$$W = [ \begin{matrix}\frac{3 \sqrt{5} - 5}{4} \cdot ( {V}_{REF \_ 1} - {V}_{REF \_ 4} ) \\ \frac{5}{2} \cdot {V}_{REF \_ 5}\end{matrix} ] = [ \begin{matrix}{V}_{M} \\ {V}_{C}\end{matrix} ]$$

This makes it possible to compute the secondary components of the secondary potential and the homopolar potential:

$${V}_{SAB} ( 1 ) = \frac{2}{5} \cdot ( 1 - cos ( \frac{π}{5} ) - 2 \cdot cos ( \frac{2 π}{5} ) ) \cdot {V}_{M} - \frac{2}{5} \cdot cos ( \frac{π}{5} ) \cdot {V}_{C}$$

$${V}_{SAB} ( 2 ) = \frac{2}{5} \cdot sin ( \frac{π}{5} ) \cdot {V}_{M} - \frac{2}{5} \cdot sin ( \frac{π}{5} ) \cdot {V}_{C}$$

$${V}_{HN} = \frac{1}{5} {V}_{C}$$

and one obtains for the potentials to be produced Vₖ (with k between 1 and 5):

$${V}_{k} = {V}_{REF \_ k} + {V}_{S \_ k} + {V}_{HN}$$

$$i . e . :$$

$$\begin{matrix}{V}_{1} = {V}_{M} \\ {V}_{2} = {V}_{M} \\ {V}_{3} = - {V}_{M} \\ {V}_{4} = - {V}_{M} \\ {V}_{5} = {V}_{C}\end{matrix}$$

FIGS. 2A, 2B and 2C show, more specifically, the implementation of the method for a five-phase motor, in the scenario in which the reference potentials V_{REF_i} determined at the start of the method are less than or equal to the second threshold and therefore the potentials to be produced Vᵢ comprise only the possible addition of a homopolar potential V_{H}.

If the drive voltage V_{MAG}=90% V_{DC}/2, the reference potentials of the five phases (curves 201a, 202a, 203a, 204a and 205a of FIG. 2A) are indeed all less than the first threshold. Thus, it is not necessary to add any homopolar potential V_{H}, or any secondary potential V_{S_i} in accordance with the method of the invention.

If the drive voltage V_{MAG}=V_{DC}/2, the reference potentials of the five phases (curves 201b, 202b, 203b, 204b and 205b of FIG. 2B) are indeed less than or equal to the first threshold. Thus, it is not necessary to add any homopolar potential V_{H}, or any secondary potential V_{S_i}.

Specifically, the maximum and minimum values of homopolar potential V_{H} represented by the curves 211b and 212b demonstrate that a homopolar potential equal to 0 does indeed make it possible to keep the potentials of the N phases between −V_{DC}/2 and +V_{DC}/2. The maximum homopolar potential is expressed by V_{DC}/2−max(V_{REF_i}) and the minimum homopolar potential is expressed by −V_{DC}/2−min(V_{REF_i}). The curve 213b represents the homopolar potential V_{H} proposed in the method of the invention, i.e. in the scenario in which the electrical potentials of the five phases are less than or equal to the second threshold but in which at least one of the reference potentials is greater than the first threshold.

If the drive voltage V_{MAG}=105% V_{DC}/2, the reference potentials of the five phases (curves 201c, 202c, 203c, 204c and 205c of FIG. 2C) reach the first threshold, but remain less than or equal to the second threshold. Thus, it is necessary to add a homopolar potential V_{H} for them to always be between −V_{DC}/2 and +V_{DC}/2. The curves 211c and 212c represent the possible maximum and minimum values of the homopolar potential V_{H} for the amplitude of the potentials to be produced of the five phases to remain less than or equal to V_{DC}/2.

The curve 213c represents the homopolar potential V_{H} proposed in the step 106 of the method 100 according to the invention. It can be seen that this curve 213c is indeed contained between the curves 211c and 212c, i.e. between the maximum and minimum values of homopolar potential possible. After application of the method 100 of the invention, it can be seen that the potentials to be produced of the five phases have indeed been corrected (curves 221c, 222c, 223c, 224c and 225c which represent the potential Vᵢ=V_{REF_i}+V_{H}) in such a way as to remain between −V_{DC}/2 and +V_{DC}/2 while being increased for certain values of angle θ so that the amplitude of the voltage across the terminals of the motor windings can rise all the way to the drive voltage V_{MAG}, i.e. 105% V_{DC}/2.

FIGS. 3A and 3B represent, more specifically, the implementation of the method for a five-phase motor, in the scenario in which at least one of the reference potentials V_{REF_i} is greater than the second threshold and thus the potentials to be produced Vᵢ comprise the addition of a homopolar potential V_{HN} dependent on the number of phases and on a secondary potential V_{S_i}.

If the drive voltage V_{MAG}=110% V_{DC}/2, the reference potentials of the five phases (curves 301a, 302a, 303a, 304a and 305a of the FIG. 3A) are greater than the first threshold and than the second threshold. Thus, in accordance with the method of the invention, it is necessary to add a homopolar potential V_{HN} and a secondary potential V_{S_i}. The grey areas around the curves 311a, 312a and 313a respectively represent the possible values of the homopolar potential V_{HN} and of the two components V_{SAB}(1) and V_{SAB}(2) of the secondary potential V_{S_i}. In particular, the curve 311a represents the first component V_{SAB}(1) of the secondary potential V_{S_i}, and the curve 312a represents the second component V_{SAB}(2) of the secondary potential V_{S_i} according to the formulae of the invention described previously. The curve 313a represents the value of the homopolar potential V_{HN} according to the formulae of the invention described previously. After application of the method of the invention, and therefore the addition of the secondary and homopolar potentials V_{S_i} (i.e. V_{SAB}(1) and V_{SAB}(2)) and V_{HN} represented by the curves 311a, 312a and 313a, the reference potentials of the five phases are corrected and the potentials to be produced are represented by the curves 321a, 322a, 323a, 324a and 325a. It can be seen that the potentials to be produced are now indeed between −V_{DC}/2 and +V_{DC}/2, and that their amplitude has indeed been modified for certain values of angle θ to increase the voltage across the terminals of the motor windings.

If the drive voltage V_{MAG} is equal to the limit voltage V_{LIM}, i.e. 123% V_{DC}/2, the reference potentials V_{REF_i} of the five phases (curves 301b, 302b, 303b, 304b and 305b of the FIG. 3B) are greater than the first threshold and than the second threshold. Thus, in accordance with the method of the invention, it is necessary to add a homopolar potential V_{HN} and a secondary potential V_{S_i}. The gray areas around the curves 311b, 312b and 313b respectively represent the possible values of the homopolar potential V_{HN} and of the components V_{SAB}(1) and V_{SAB}(2) of the secondary potential V_{S_i}. Unlike the scenario of FIG. 3A, it can be seen that the area around the curves 311b, 312b and 313b has shrunk and that there is now virtually only a single possible value for each component and potential to achieve the drive voltage V_{MAG} and keep the potentials to be produced of the five phases between −V_{DC}/2 and +V_{DC}/2. After application of the method of the invention, and therefore the addition of the secondary components V_{SAB}(1) and V_{SAB}(2) of the secondary potential V_{S_i} and of the homopolar potential V_{HN} represented by the curves 311b, 312b and 313b, the reference potentials V_{REF_i} of the five phases are corrected and the potentials to be produced Vᵢ are represented by the curves 321b, 322b, 323b, 324b and 325b. It can be seen that these potentials to be produced Vᵢ are indeed between −V_{DC}/2 and +V_{DC}/2, and that their amplitude has indeed been modified for certain values of angle θ to increase the voltage across the terminals of the motor windings.

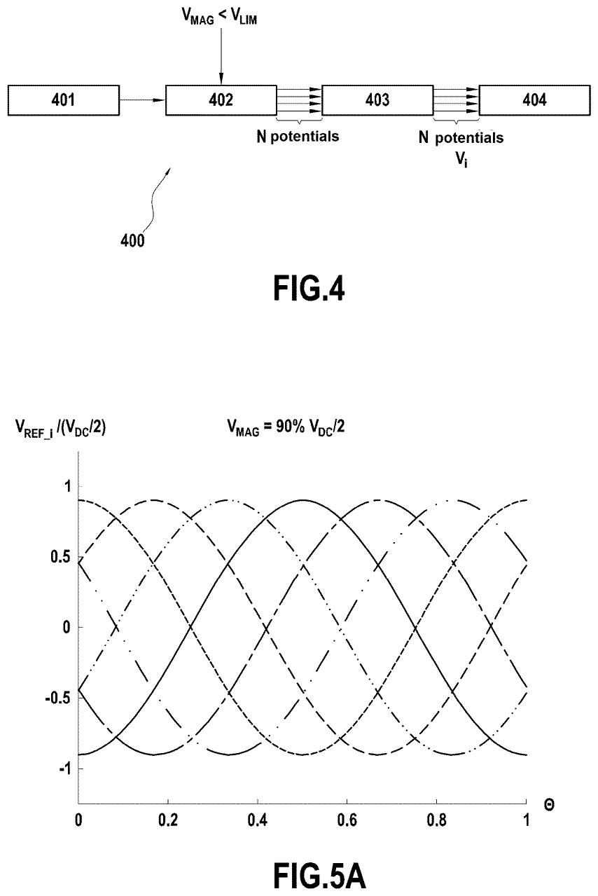

FIG. 4 represents, schematically and partially, an electric device 400 according to an embodiment of the invention.

The electric device 400 comprises an electric power supply 401 connected to an input of an electric controller 402. The electric controller 402 is connected to a power converter 403 which is itself connected to an electric motor 404 comprising N phases, N being an integer greater than or equal to 4. The electric controller 402 provides N electrical potentials to the converter 403 so that it can convert them and provide them to the N phases of the electric motor 404. The potentials provided to the motor 404 correspond to the potentials to be produced Vᵢ determined by the method of the invention and converted by the power converter 403.

The electric controller 402 is particularly configured to implement the method of the invention. Thus, the controller 402 is configured to determine the reference potentials and the potentials to be produced Vᵢ of the N phases of the motor 404 for a drive voltage V_{MAG} less than a limit voltage V_{LIM} provided by a user, as shown on FIG. 4, or defined by the controller 402 according to the following formula:

$${V}_{LIM} = \frac{{V}_{DC}}{2} \frac{2}{N} cos ( α ) {\sum }_{j = 0}^{N - 1} \vert cos ( \frac{2 π}{N} j ) \vert$$

with α=π/(2N) if N is odd or α=0 if N is even and a multiple of 4 or α=π/N if N is even and a non-multiple of 4.

The electrical potentials to be produced Vᵢ are determined according to the values of the reference electrical potentials V_{REF_i} determined by the controller 402, the reference potentials V_{REF_i} being given by the following formula:

$${V}_{REF \_ i} = {V}_{MAG} cos ( θ - \frac{2 π}{N} ( i - 1 ) )$$

with i between 1 and N, and V_{REF_i} representing the reference potential of the i-th phase of the motor 404.

Then the controller 402 compares these reference potentials V_{REF_i} to the first and second thresholds, which can be defined as indicated with reference to FIG. 1.

If the reference potentials V_{REF_i} are all less than or equal to the first threshold, then the potentials Vᵢ provided to the power converter 403 then to the motor 404 will be equal to the reference potentials V_{REF_i} previously described.

If the reference potentials V_{REF_i} are all less than or equal to the second threshold, but at least one of the reference potentials is greater than the first threshold, then the potentials Vᵢ provided to the power converter 403 then to the motor 404 will be equal to Vᵢ=V_{REF_i}+V_{H}, with V_{H} the homopolar potential defined by the following formula:

$${V}_{H} = \frac{{max}_{k = 1 … N} ( {V}_{{REF}_{k}} ) + {min}_{k = 1 … N} ( {V}_{{REF}_{k}} )}{2}$$

where

$${max}_{k = 1 … N} {V}_{{REF}_{k}}$$

represents the maximum reference potential from among the reference potentials V_{REF_i} determined previously and

$${min}_{k = 1 … N} {V}_{{REF}_{k}}$$

represents the minimum reference potential from among the reference potentials V_{REF_i} determined previously.

If the reference potentials V_{REF_i} are all greater than the second threshold, then the potentials Vᵢ provided to the power converter 403 then to the motor 404 will be equal to Vᵢ=V_{REF_i}+V_{S_i}+V_{HN}, with V_{HN} a homopolar potential dependent on the number of phases N and on the reference electrical potentials V_{REF_i} and V_{S_i} a secondary potential dependent on the number of phases N and on the reference electrical potentials V_{REF_i}.

In this scenario, the secondary V_{S_i} and homopolar V_{HN} potentials can be expressed by the following functions:

$$( \begin{matrix}{V}_{{S}_{1}} \\ ⋮ \\ {V}_{{S}_{N}}\end{matrix} ) = T ( : , 3 : N - 1 ) ( \begin{matrix}{V}_{{SAB}_{1}} \\ ⋮ \\ {V}_{{SAB}_{N - 1}}\end{matrix} )$$

with:
if N is odd, with p=(N−1)/2:

$${V}_{SABi} ( k ) = \frac{[ U ( k + 2 ) V ( 2 ) - U ( 2 ) V ( k + 2 ) ] [ V ( k + 2 ) U ( 1 ) - V ( 1 ) U ( k + 2 ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$

k ranging from 1 to N−3, and

$${V}_{HN} = \frac{1}{\sqrt{2}} \frac{[ U ( N ) V ( 2 ) - U ( 2 ) V ( N ) ] [ V ( N ) U ( 1 ) - V ( 1 ) U ( N ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF\_N}\end{matrix} )$$

with:
U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference potentials V_{REF_i};
iN the p indices of the p smallest values of the reference potentials V_{REF_i};
iM the index of the median value of the reference potentials V_{REF_i};
i varying from 1 to N, and
T a transformation matrix defined by:
   the odd columns from 1 to 2 [(N−1)/2] written 2k−1 (k varying from 1 to [(N−1)/2]), correspond to the vector having as i-th component (with i varying from 1 to N): c(i, 2k−1)=cos(2πk(i−1)/N);
   the even columns from 1 to 2 [(N−1)/2] written 2k (k varying from 1 to [(N−1)/2]) correspond to the vector having as i-th component (with i varying from 1 to N): c(i, 2k)=sin(2πk(i−1)/N);
   if N is odd, the column N is defined by a constant vector with the value 1/√2;
   if N is even, the column N−1 is defined by a vector of alternate constants of value 1/√2 and of value −1/√2 and the column N is defined by a constant vector with the value 1/√2.
      If N is even, with p=N/2: V_{H}=0 and V_{SAB_i}(k) is defined by:
If k varies from 1 to p−2:

$${V}_{SABi} ( 2 + k + 2 ⌊ ( k - 1 ) / 2 ⌋ ) = {Q}^{- 1} \cdot ( \begin{matrix}{V}_{M} - {V}_{REF iP ( 1 )} \\ ⋮ \\ {V}_{M} - {V}_{REF iP ( p - 2 )}\end{matrix} )$$

For other values of k between 1 and N−3: V_{SAB_i}(k)=0;
   with:

$${V}_{M} = - \frac{{V}_{{REF}_{iP ( p - 1 )}} - {p}_{M} ( \begin{matrix}{V}_{REF \_ iP ( 1 )} \\ ⋮ \\ {V}_{REF \_ iP ( p - 2 )}\end{matrix} )}{1 - {p}_{M} ( \begin{matrix}1 \\ ⋮ \\ 1\end{matrix} )}$$

$${p}_{M} = {qQ}^{- 1} ;$$

iP the p−1 indices of the p−1 greatest values of the reference potentials V_{REF_i} for i varying from 1 to N;
q the row vector formed of the elements of the row of the transformation matrix T corresponding to the last index of iP corresponding to the columns indexed

$$4 + k + 2 ⌊ \frac{k - 1}{2} ⌋$$

where k varies from 1 to p−2; and
Q the matrix formed of the elements of the transformation matrix T at the intersection of the rows corresponding to the p−2 first indices of the iP and of the columns indexed

$$4 + k + 2 ⌊ \frac{k - 1}{2} ⌋$$

where k varies from 1 to p−2.

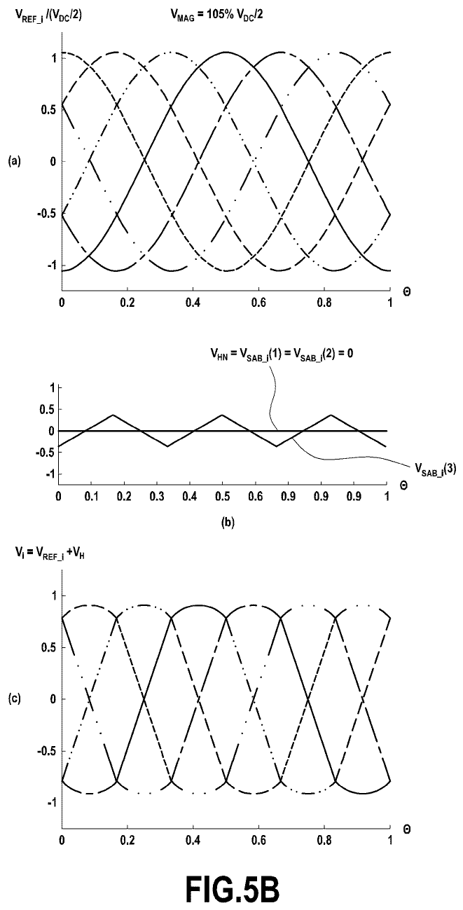

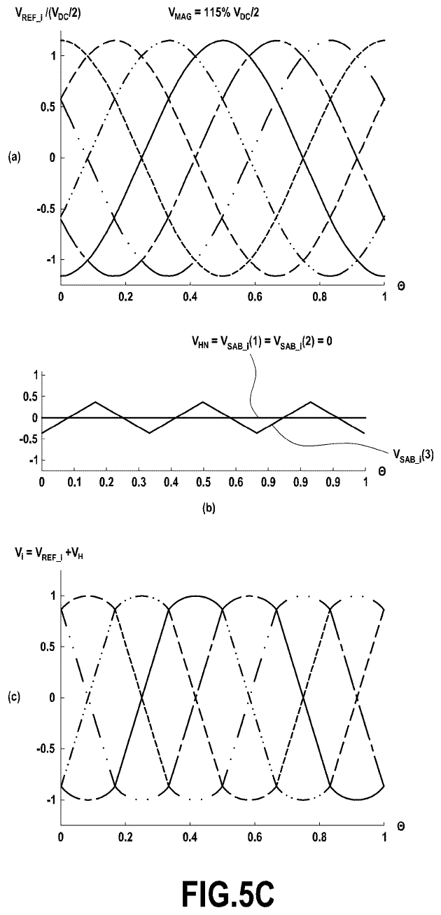

FIGS. 5A, 5B and 5C show another exemplary implementation of the method according to the invention for N=6, i.e. for a six-phase motor.

For a six-phase motor, the transformation matrix T is expressed as follows:

$$T = ( \begin{matrix}cos ( \frac{2 π}{6} \cdot 0 ) & sin ( \frac{2 π}{6} \cdot 0 ) & cos ( \frac{4 π}{6} \cdot 0 ) & sin ( \frac{4 π}{6} \cdot 0 ) & \frac{\sqrt{2}}{2} & \frac{\sqrt{2}}{2} \\ cos ( \frac{2 π}{6} \cdot 1 ) & sin ( \frac{2 π}{6} \cdot 1 ) & cos ( \frac{4 π}{6} \cdot 1 ) & sin ( \frac{4 π}{6} \cdot 1 ) & - \frac{\sqrt{2}}{2} & \frac{\sqrt{2}}{2} \\ cos ( \frac{2 π}{6} \cdot 2 ) & sin ( \frac{2 π}{6} \cdot 2 ) & cos ( \frac{4 π}{6} \cdot 2 ) & sin ( \frac{4 π}{6} \cdot 2 ) & \frac{\sqrt{2}}{2} & \frac{\sqrt{2}}{2} \\ cos ( \frac{2 π}{6} \cdot 3 ) & sin ( \frac{2 π}{6} \cdot 3 ) & cos ( \frac{4 π}{6} \cdot 3 ) & sin ( \frac{4 π}{6} \cdot 3 ) & - \frac{\sqrt{2}}{2} & \frac{\sqrt{2}}{2} \\ cos ( \frac{2 π}{6} \cdot 4 ) & sin ( \frac{2 π}{6} \cdot 4 ) & cos ( \frac{4 π}{6} \cdot 4 ) & sin ( \frac{4 π}{6} \cdot 4 ) & \frac{\sqrt{2}}{2} & \frac{\sqrt{2}}{2} \\ cos ( \frac{2 π}{6} \cdot 5 ) & sin ( \frac{2 π}{6} \cdot 5 ) & cos ( \frac{4 π}{6} \cdot 5 ) & sin ( \frac{4 π}{6} \cdot 5 ) & - \frac{\sqrt{2}}{2} & \frac{\sqrt{2}}{2}\end{matrix} )$$

As N is even, in accordance with the invention, the reference electrical potentials V_{REF_i} across the terminals of the six phases for a drive voltage V_{MAG} are defined by:

$${V}_{REF \_ i} = T ( i , 1 : 2 ) \cdot ( \begin{matrix}{V}_{MAG} \cdot cos ( θ ) \\ {V}_{MAG} \cdot sin ( θ )\end{matrix} )$$

with i between 1 and 6.

Then, applying the formulae of the invention, as N is even, the homopolar potential V_{HN} is zero and the secondary potentials are defined by:

$${V}_{SAB \_ i} ( 1 ) = {V}_{SAB \_ i} ( 2 ) = 0$$

$${V}_{SAB \_ i} ( 3 ) = \frac{{V}_{M} - {V}_{REF \_ iP ( 1 )}}{T ( iP ( 1 ) , 5 )}$$

$$with$$

$${V}_{M} = \frac{{V}_{REF \_ iP ( 1 )} + {V}_{REF \_ iP ( 2 )}}{2}$$

The electrical potentials to be produced Vᵢ across the terminals of the six phases are then equal to:

$${V}_{i} = {V}_{REF \_ k} - {( - 1 )}^{iP ( 1 ) + k} \times \frac{{V}_{REF \_ iP ( 1 )} - {V}_{REF \_ iP ( 2 )}}{2}$$

FIG. 5A represents the reference electrical potential V_{REF_i} across the terminals of the six phases of the six-phase motor before the application of the method of the invention for a drive voltage V_{MAG} of amplitude equal to 90% of V_{DC}/2.

In this scenario, the reference potentials of the six phases are all indeed less than V_{DC}/2, which is the first threshold. It is therefore not necessary to add any secondary potential in accordance with the method of the invention. The potentials to be produced are therefore equal to the reference electrical potentials V_{REF_i}.

FIG. 5B represents the reference electrical potential V_{REF_i} across the terminals of the six phases of the six-phase motor before the application of the method of the invention (graph (a)), the secondary potential V_{SAB_i}(3) as described previously (graph (b)) as well as the potentials to be produced Vᵢ (graph (c)) for a drive voltage V_{MAG} of amplitude equal to 105% of V_{DC}/2.

FIG. 5C represents the reference electrical potential V_{REF_i} across the terminals of the six phases of the six-phase motor before the application of the method of the invention (graph (a)), the secondary potential V_{SAB_i}(3) as described previously (graph (b)) as well as the potentials to be produced Vᵢ (graph (c)) for a drive voltage V_{MAG} of amplitude equal to 115.7% of V_{DC}/2.

1. A method, implemented by an electric controller, for determining electrical potentials (Vᵢ) to be produced across the terminals of the phases of a motor comprising N phases, N being an integer greater than or equal to 4, the method comprising the following steps:
defining a drive voltage of amplitude V_{MAG} and of phase θ which is less than a limit voltage;
determining reference electrical potentials across the terminals of the N phases of the motor for this drive voltage with
$${V}_{REF \_ i} = {V}_{MAG} cos ( θ - \frac{2 π}{N} ( i - 1 ) )$$
where i is between 1 and N, V_{REF_i} is the reference electrical potential across the terminals of the i-th phase and θ is the phase of the drive voltage between 0 and 2π;
comparing the reference electrical potentials to a first threshold;
if the reference electrical potentials are all less than or equal to the first threshold, then the electrical potentials to be produced across the terminals of the N phases of the motor are equal to the reference electrical potentials, or if at least one of the reference electrical potentials is greater than the first threshold, comparing these reference electrical potentials to a second threshold, the second threshold being greater than the first threshold;
if these reference electrical potentials are all less than or equal to the second threshold, then the electrical potentials to be produced across the terminals of the N phases of the motor are equal to Vᵢ=V_{REF_i}+V_{H}, with
$${V}_{H} = \frac{{max}_{k = 1 \_ N} ( {V}_{{REF}_{k}} ) + {min}_{k = 1 \_ N} ( {V}_{{REF}_{k}} )}{2}$$
or if at least one of the reference electrical potentials is greater than the second threshold, then the electrical potentials to be produced across the terminals of the N phases of the motor are equal to Vᵢ=V_{REF_i}+V_{S_i}+V_{HN}, with V_{HN} a homopolar potential dependent on the number of phases and on the reference electrical potentials and V_{S_i} a secondary potential dependent on the number of phases and on the reference electrical potentials.

2. The determining method as claimed in claim 1, wherein when at least one of the reference potentials is greater than the second threshold, the secondary and homopolar potentials are expressed by the following functions:
$$( \begin{matrix}{V}_{{S}_{1}} \\ ⋮ \\ {V}_{{S}_{N}}\end{matrix} ) = T ( : , 3 : N - 1 ) ( \begin{matrix}{V}_{{SAB}_{1}} \\ ⋮ \\ {V}_{{SAB}_{N - 1}}\end{matrix} )$$
with:
if N is odd, with p=(N−1)/2:
$${V}_{SABI} ( k ) = \frac{[ U ( k + 2 ) V ( 2 ) - U ( 2 ) V ( k + 2 ) ] [ V ( k + 2 ) U ( 1 ) - V ( 1 ) U ( k + 2 ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ N}\end{matrix} )$$
with k ranging from 1 to N−3, and
$${V}_{HN} = \frac{1}{\sqrt{2}} \frac{[ U ( N ) V ( 2 ) - U ( 2 ) V ( N ) ] [ V ( N ) U ( 1 ) - V ( 1 ) U ( N ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF \_ 2}\end{matrix} )$$
U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference electrical potentials;
iN the p indices of the p smallest values of the reference electrical potentials;
iM the index of the median value of the reference electrical potentials;
i varying from 1 to N, and
T a transformation matrix defined by:
the odd columns from 1 to 2 [(N−1)/2] written 2k−1 (k varying from 1 to [(N−1)/2]), correspond to the vector having as i-th component (with i varying from 1 to N): c(i, 2k−1)=cos(2πk(i−1)/N);
the even columns from 1 to 2 [(N−1)/2 ] written 2k (k varying from 1 to [(N−1)/2]) correspond to the vector having as i-th component (with i varying from 1 to N):
if N is odd, the column N is defined by a constant vector with the value 1/√2;
if N is even, the column N−1 is defined by a vector of alternate constants of value 1/√2 and of value −1/√2 and the column N is defined by a constant vector with the value 1/√2.
If N is even, with p=N/2: V_{HN}=0 and V_{SAB_i}(k) is defined by:
If k varies from 1 to p−2:
$${V}_{SABI} ( 2 + k + 2 ⌊ ( k - 1 ) / 2 ⌋ ) = {Q}^{- 1} \cdot ( \begin{matrix}{V}_{M} - {V}_{REF IP ( 1 )} \\ ⋮ \\ {V}_{M} - {V}_{REF IP ( 2 )}\end{matrix} )$$
For other values of k between 1 and N−3: V_{SAB_i}(k)=0;
with
$${V}_{M} = - \frac{{V}_{{REF}_{ip ( p - 1 )}} - {p}_{M} ( \begin{matrix}{V}_{REF \_ iP ( 1 )} \\ ⋮ \\ {V}_{REF \_ iP ( p - 2 )}\end{matrix} )}{1 - {p}_{M} ( \begin{matrix}1 \\ ⋮ \\ 1\end{matrix} )}$$
$${p}_{M} = {qQ}^{- 1} ;$$
iP the p−1 indices of the p−1 greatest values of the reference electrical potentials for i varying from 1 to N;
q the row vector formed of the elements of the row of the transformation matrix T corresponding to the last index of iP corresponding to the columns indexed
$$4 + k + 2 ⌊ \frac{k - 1}{2} ⌋$$
where k varies from 1 to p−2; and
Q the matrix formed of the elements of the transformation matrix T at the intersection of the rows corresponding to the p−2 first indices of the iP and of the columns indexed
$$4 + k + 2 ⌊ \frac{k - 1}{2} ⌋$$
where k varies from 1 to p−2.

3. The determining method according to claim 1, wherein the limit voltage and the second threshold are functions dependent on the number of phases of the motor and on the electrical potential of an electrical power supply of the motor.

4. The determining method according to claim 1, wherein the first threshold is a function dependent on the electrical potential of the electrical power supply of the motor.

5. The determining method according to claim 1, wherein the second threshold is expressed by the following function:
$$seuil 2 = \frac{{V}_{DC}}{2} \frac{1}{sin ( \frac{π}{N} + \frac{π}{N} \cdot ⌊ \frac{N}{2} ⌋ )}$$

6. The determining method according to claim 1, wherein the limit voltage is expressed by the following function:
$${V}_{LIM} = \frac{{V}_{DC}}{2} \frac{2}{N} cos ( α ) {\sum }_{j = 0}^{N - 1} \vert cos ( \frac{2 π}{N} j ) \vert$$
with α=π/(2N) if N is odd or α=0 if N is even and a multiple of 4 or α=π/N if N is even and a non-multiple of 4.

7. The determining method according to claim 1, wherein the first threshold is equal to V_{DC}/2.

8. The determining method according to claim 1, wherein the motor is a five-phase motor, N is equal to 5, the first threshold is equal to V_{DC}/2, the second threshold is equal to 1.05×V_{DC}/2 and the limit voltage is equal to 1.23×V_{DC}/2 with V_{DC} the electrical potential of the electrical power supply of the motor, and if at least one of the reference electrical potentials is greater than the second threshold, then the electrical potentials to be produced across the terminals of the 5 phases of the motor are equal to Vᵢ₍ᵢ₌ₚ₎=V_{M} for p, such that the reference electrical potentials V_{REF_p} are the two largest reference electrical potentials, Vᵢ₍ᵢ₌ₗ₎=−V_{M} for l, such that the reference electrical potentials V_{REF_l} are the two smallest reference electrical potentials or Vᵢ₍ᵢ₌ⱼ₎=V_{C} for j, such that the reference electrical potential V_{REF_j} is the median reference electrical potential, with:
$${V}_{M} = \frac{3 \sqrt{5} - 5}{4} ( {max}_{k = 1 ... 5} ( {V}_{REF k} ) - {min}_{k = 1 ... 5} ( {V}_{REF k} ) )$$
$$and$$
$${V}_{C} = \frac{5}{2} {median}_{k = 1 ... 5} ( {V}_{REF k} )$$
with p, j and l chosen from among {1; 2; 3; 4; 5} and p≠j≠l.

9. An electric controller intended to be connected to a motor with N phases and to an electrical power supply source, with N an integer greater than or equal to 4, the controller being configured to
define a drive voltage of amplitude V_{MAG} and of phase θ which is less than a limit voltage;
determine reference electrical potentials across the terminals of the N phases of the motor for the drive voltage with
$${V}_{REF\_t} = {V}_{MAG} cos ( θ - \frac{2 π}{N} ( i - 1 ) )$$
where i is between 1 and N, V_{REF_i} is the reference electrical potential across the terminals of the i-th phase and θ is the phase of the drive voltage between 0 and 2π;
compare the reference electrical potentials to a first threshold;
if the reference electrical potentials are all less than or equal to the first threshold, then the electrical potentials to be produced across the terminals of the N phases of the motor are equal to the reference electrical potentials, or if at least one of the reference electrical potentials is greater than the first threshold, compare these reference electrical potentials to a second threshold, the second threshold being greater than the first threshold;
if these reference electrical potentials are all less than or equal to the second threshold, then the electrical potentials to be produced across the terminals of the N phases of the motor are equal to Vᵢ=V_{REF_i}+V_{H}, with
$${V}_{H} = \frac{{max}_{k = 1 ... N} ( {V}_{{REF}_{k}} ) + {min}_{k = 1 ... N} ( {V}_{{REF}_{k}} )}{2}$$
or if at least one of the reference potentials is greater than the second threshold, then the potentials to be produced across the terminals of the N phases of the motor are equal to Vᵢ=V_{REF_i}+V_{S_i}+V_{HN}, with V_{HN} a homopolar potential dependent on the number of phases and on the reference electrical potentials and V_{S_i} a secondary potential dependent on the number of phases and on the reference electrical potentials.

10. The electric controller as claimed in claim 9, wherein when at least one of the reference potentials is greater than the second threshold, the secondary and homopolar potentials are expressed by the following functions:
$$( \begin{matrix}{V}_{{S}_{1}} \\ ⋮ \\ {V}_{{S}_{q}}\end{matrix} ) = T ( : , 3 : N - 1 ) ( \begin{matrix}{V}_{{SAB}_{1}} \\ ⋮ \\ {V}_{{SAB}_{q \cdot 3}}\end{matrix} )$$
with:
if N is odd, with p=(N−1)/2:
$${V}_{SABi} ( k ) = \frac{[ U ( k + 2 ) V ( 2 ) - U ( 2 ) V ( k + 2 ) ] [ V ( k + 2 ) U ( 1 ) - V ( 1 ) U ( k + 2 ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF\_N}\end{matrix} )$$
with k ranging from 1 to N−3, and
$${V}_{HN} = \frac{1}{\sqrt{2}} \frac{[ U ( N ) V ( 2 ) - U ( 2 ) V ( N ) ] [ V ( N ) U ( 1 ) - V ( 1 ) U ( N ) ]}{U ( 1 ) V ( 2 ) - U ( 2 ) V ( 1 )} {T}^{- 1} ( 1 : 2 , : ) ( \begin{matrix}{V}_{REF \_ 1} \\ ⋮ \\ {V}_{REF\_N}\end{matrix} )$$
U a vector with N rows defined by U=T⁻¹u and u a vector with N rows defined by a value 1 for its indices iP, a value 0 for its index iM and a value −1 for its indices iN;
V a vector with N rows defined by V=T⁻¹v and v a vector with N rows defined by a value 0 for its indices iP and iN and a value 1 for its index iM;
iP the p indices of the p greatest values of the reference electrical potentials;
iN the p indices of the p smallest values of the reference electrical potentials;
iM the index of the median value of the reference electrical potentials;
i varying from 1 to N, and
T a transformation matrix defined by:
the odd columns from 1 to 2 [(N−1)/2] written 2k−1 (k varying from 1 to [(N−1)/2]), correspond to the vector having as i-th component (with i varying from 1 to N): c(i, 2k−1)=cos(2πk(i−1)/N);
the even columns from 1 to 2[(N−1)/2 ] written 2k (k varying from 1 to [(N−1)/2]) correspond to the vector having as i-th component (with i varying from 1 to N):
if N is odd, the column N is defined by a constant vector with the value
if N is even, the column N−1 is defined by a vector of alternate constants of value 1/√2 and of value −1/√2 and the column N is defined by a constant vector with the value 1/√2.
If N is even, with p=N/2: V_{H}=0 and V_{SAB_i}(k) is defined by:
If k varies from 1 to p−2:
$${V}_{SABi} ( 2 + k + 2 ⌊ ( k - 1 ) / 2 ⌋ ) = {Q}^{- 1} \cdot ( \begin{matrix}{V}_{M} - {V}_{REF iP ( 1 )} \\ ⋮ \\ {V}_{M} - {V}_{REF iP ( p - 2 )}\end{matrix} )$$
For other values of k between 1 and N−3: V_{SAB_i}(k)=0;
with
$${V}_{M} = - \frac{{V}_{{REF}_{iP ( p - 1 )}} - {p}_{M} ( \begin{matrix}{V}_{REF\_iP ( 1 )} \\ ⋮ \\ {V}_{REF\_iP ( p - 2 )}\end{matrix} )}{1 - {p}_{M} ( \begin{matrix}1 \\ ⋮ \\ 1\end{matrix} )}$$
$${ρ}_{M} = {qQ}^{- 1} ;$$
iP the p−1 indices of the p−1 greatest values of the reference electrical potentials for i varying from 1 to N;
q the row vector formed of the elements of the row of the transformation matrix T corresponding to the last index of iP corresponding to the columns indexed
$$4 + k + 2 ⌊ \frac{k - 1}{2} ⌋$$
where k varies from 1 to p−2; and
Q the matrix formed of the elements of the transformation matrix T at the intersection of the rows corresponding to the p−2 first indices of the iP and of the columns indexed
$$4 + k + 2 ⌊ \frac{k - 1}{2} ⌋$$
where k varies from 1 to p−2.

11. The electric controller according to claim 9, wherein the limit voltage and the second threshold are functions dependent on the number of phases of the motor and on the electrical potential of the electrical power supply intended to be connected to the electric controller.

12. The electric controller according to claim 9, wherein the second threshold is expressed by the following function:
$$seuil 2 = \frac{{V}_{DC}}{2} \frac{1}{sin ( \frac{π}{N} + \frac{π}{N} \cdot \vert \frac{N}{2} \vert )}$$
with V_{DC} the voltage of the electrical power supply intended to be connected to the electric controller and N the number of phases of the motor intended to be connected to the electric controller.

13. The electric controller according to claim 9, wherein the limit voltage is expressed by the following function:
$${V}_{LIM} = \frac{{V}_{DC}}{2} \frac{2}{N} cos ( α ) {\sum }_{i = 0}^{N - 1} \vert cos ( \frac{2 π}{N} j ) \vert$$
with α=π/(2N) if N is odd or α=0 if N is even and a multiple of 4 or α=π/N if N is even and a non-multiple of 4, and with V_{DC} the voltage of the electrical power supply intended to be connected to the electric controller and N the number of phases of the motor intended to be connected to the electric controller.

14. An electric device comprising:
an electrical power supply source;
an electric controller according to claim 9, an input of which is connected to the electrical power supply source;
a power converter, inputs of which are connected to the electric controller;
a motor with N phases connected to the power converter,
N being an integer greater than or equal to 4, and the power converter being configured to provide electrical potentials as input to the N phases of the motor.
